(19) United States
(12) Patent Application Publication
(10) Pub. No.: US 2010/0032824 A1
(43) Pub. Date: Feb. 11, 2010

(54) IC Package Method Capable of Decreasing IR Drop and Associated IC Apparatus

(75) Inventors: CHIH-AN YANG, Hsinchu Hsien (TW); MING-CHUNG CHANG, Hsinchu Hsien (TW)

Correspondence Address: WPAT, PC;INTELLECTUAL PROPERTY ATTORNEYS, 7225 BEVERLY ST., ANNANDALE, VA, 22003, US

(73) Assignee: MSTAR SEMICONDUCTOR, INC., Hsinchu Hsien (TW)

(21) Appl. No.: 12/368,384

(22) Filed: Feb. 10, 2009

(30) Foreign Application Priority Data
Aug. 8, 2008 (TW) 097130328

(51) Int. Cl. H01L 23/482; H01L 21/56

(52) U.S. Cl. 257/691; 438/123; 257/E23.015; 257/E21.502

(57) ABSTRACT

An IC package method capable of decreasing IR drop of a chip and associated IC apparatus is provided. The IC package method comprises forming a lead frame including a die paddle and a plurality of fingers; installing a die on the die paddle, and coupling a plurality of signal terminals of the die to the fingers; forming a power transferring unit coupled to a power supply; coupling power reception terminals of a plurality of logic units in the die to the power transferring unit; and forming a housing for encapsulating the die, the lead frame and the power transferring unit.

### FIELD OF THE INVENTION

The present invention relates to an IC package. More particularly, the present invention relates to an IC package method capable of decreasing IR drop and associated IC apparatus.

### BACKGROUND OF THE INVENTION

IC packaging is a part of the back-end manufacturing process in the semiconductor industry. In IC packaging, dies from a wafer are cut, attached, bonded with external fingers, and encapsulated. A finished product in a package form serves as an interface for connections between internal electrical signals to a system via a packaging material such as fingers. The package also prevents the internal integrated circuit from damages caused by external forces, water, humidity and chemicals as well as etching. Common IC package types include dual in-line package (DIP), plastic quad flat package (PQFP), plastic flat package (PFP), pin grid array package (PGA), and ball grid array package (BGA).

An IC package is primarily consisted of a die, a lead frame, and a housing. FIG. 1 shows a sectional view of a prior IC apparatus 10. The IC apparatus 10 comprises a die 102, a die paddle 104, fingers 106, gold wires 108 and a housing 100. Being a core unit of the IC apparatus 10, the die 102 performs analog and/or digital signal processing. The die paddle 104 and the fingers 106 form a lead frame for holding the die 102 and soldering the gold wires 108 such that signals are conducted thereon. The housing 100 fills up a cavity to protect the IC apparatus 10, and may be made of ceramic or plastic such as an epoxy molding compound (EMC). Generally speaking, inductance of the gold wires 108 and the fingers 106 is 1 nH/mm and 0.8 nH/mm in average, respectively. For instance, in a 256-finger low profile quad flat package (LQFP), the golden wires 108 and the fingers 106 have lengths of 3 mm and 8 to 10 mm, respectively, and introduce inductance of approximately 10.2 nH.

Prior to the 0.25 μm manufacturing process, a power grid on the die 102 was considered as an ideal power network. In fact, a hypothesis of the kind is incorrect. Especially when IC manufacturing evolves to the 0.18 μm process and even ultra deep submicron, a width of the wires gets smaller and smaller, resulting in the resistance raises. Under the circumstances, impedance characteristics of all interconnections, including the power network, become extremely noticeable, such that supply voltage and ground voltage of the integrated circuit rise or drop. The voltages are no longer stable. This phenomenon is known as IR drop. Amplitude of the supply voltage drop depends on the amplitude of equivalent inductance between power pads and logic gates.

FIG. 2 shows a schematic diagram of a logic circuit 20 in the die 102. G1, G2, G3 and G4 represent logic units. R11 to R18 represent equivalent resistors for corresponding routes. I_{G1}, I_{G2}, I_{G3} and I_{G4} represent currents consumed by the logic units G1, G2, G3 and G4, respectively. The logic circuit 20 receives a supply voltage V_{DD} and a ground voltage V_{SS} via a pad 1 and a pad 2, respectively. During toggling, assume only the logic unit G4 is in operation while the remaining logic units have a zero current. The supply voltage V_{DD} at the logic unit G4 drops by I_{G4}×(R11+R12+R13+R14), and the supply voltage V_{DD} at the logic unit G2 drops by I_{G2}×(R11+R12). In other words, the current of each logic unit results in IR drop of various degrees with respect to other logic units. Supposing the logic units connected to the gold wires toggle concurrently, IR drop resulted is rather large. However, in certain applications, concurrent toggling is necessary, like in a clock network and registers driven by the same. When a certain number of adjacent logic units concurrently toggle, IR drop is incurred locally. Moreover, IR drop is also incurred locally when a certain section of the power grid has irregularly high impedance.

When the IR drop in a chip gets too high, logic units are nevertheless prone to malfunctioning that leads to complete failure of the entire chip although logic simulations may indicate that design are correct. Usually re-layout is the only solution to solve the foregoing problem. Therefore, power design is one key factor that establishes whether a chip design is successful or not.

### SUMMARY OF THE INVENTION

Therefore, the primary object of the invention is to provide an IC package method and a related IC apparatus capable of decreasing IR drop of a chip.

An IC package method capable of decreasing IR drop of a chip according to the invention comprises forming a lead frame including a die paddle and a plurality of fingers; installing a die on the die paddle, and coupling a plurality of signal terminals of the die to the fingers; forming a power transferring unit coupled to a power supply; coupling power reception terminals of a plurality of logic units in the die to the power transferring unit; and forming a housing for encapsulating the die, the lead frame and the power transferring unit.

An IC apparatus capable of decreasing IR drop of a chip according to the invention comprises a lead frame including a die paddle and a plurality fingers; a power transferring unit coupled to a power; a die installed on the die paddle, having a plurality of signal terminals coupled to the fingers, and a plurality of power reception terminals coupled to the power transferring unit; and a housing for encapsulating the die, the lead frame and the power transferring unit.

### BRIEF DESCRIPTION OF THE DRAWINGS

The present invention will become more readily apparent to those ordinarily skilled in the art after reviewing the following detailed description and accompanying drawings, in which:

FIG. 1 is a sectional view of a prior IC apparatus.

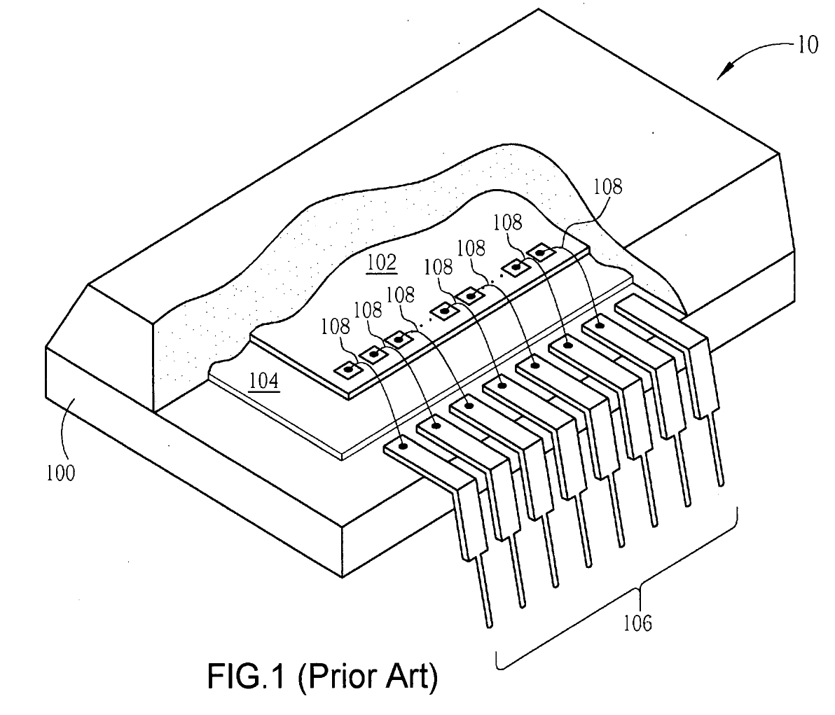

FIG. 2 is a schematic diagram of internal circuit in a die in FIG. 1.

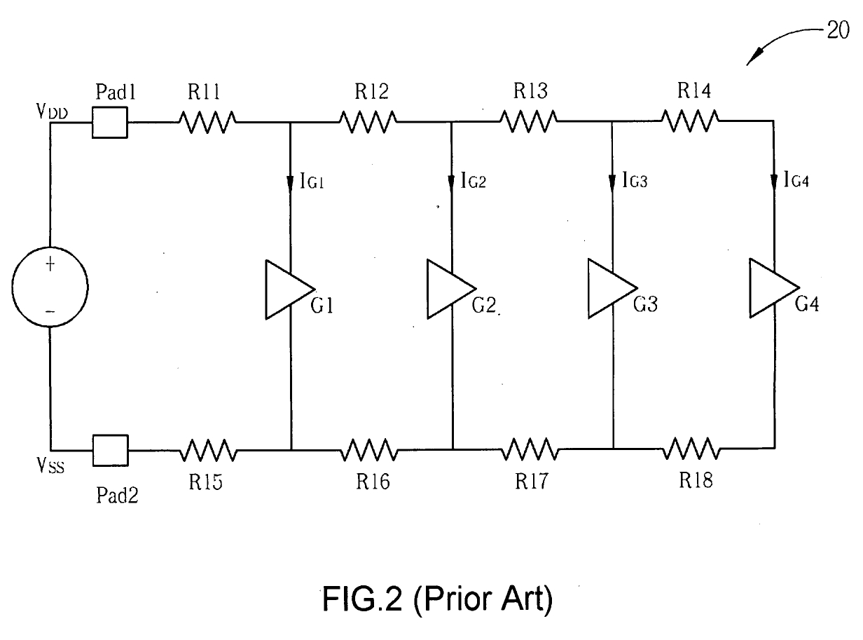

FIG. 3 is a flow chart of an IC package method according to one embodiment of the invention.

FIG. 4 is a schematic diagram of internal circuit in a die according to one embodiment of the invention.

FIG. 5 is a sectional view of an IC apparatus according to one embodiment of the invention.

FIG. 6 is a sectional view of an IC apparatus according to one embodiment of the invention.

FIG. 7 is a top perspective view of the IC apparatus in FIG. 6.

FIG. 8 is a sectional view of an IC apparatus according to one embodiment of the invention.

FIG. 9 is a top perspective view of the IC apparatus in FIG. 8.

FIG. 10 is a side perspective view of the IC apparatus in FIG. 8.

FIG. 11 is a schematic diagram of the IC apparatus in FIG. 8 provided with power transferring units.

FIG. 12 is a schematic diagram of the IC apparatus in FIG. 8 provided with power transferring subunits.

### DETAILED DESCRIPTION OF THE PREFERRED EMBODIMENT

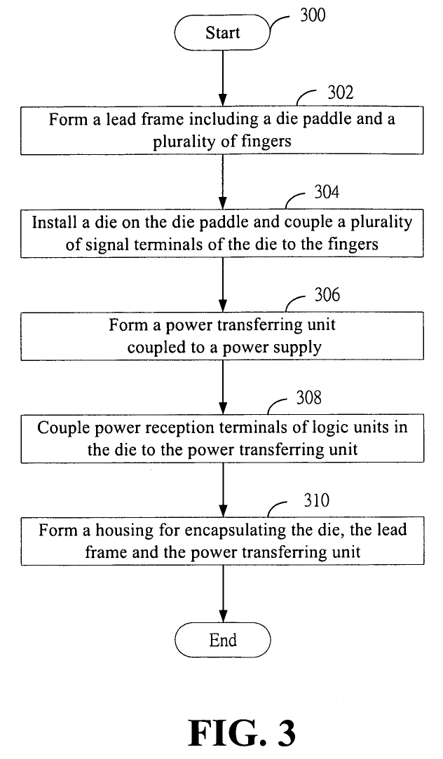

Referring to FIG. 3 showing a flow chart of an IC package method 30 according to one embodiment of the invention, the IC package method 30 capable of decreasing IC drop of an IC comprises the steps hereinafter. The procedure starts at Step 300. In Step 302, form a lead frame including a die paddle and a plurality of fingers. In Step 304, install a die on the die paddle, and couple a plurality of signal terminals of the die to the fingers. In Step 306, form a power transferring unit coupled to a power supply. In Step 308, couple power reception terminals of logic units in the die to the power transferring unit. In Step 310, form a housing for encapsulating the die, the lead frame and the power transferring unit. The procedure terminates at Step 312.

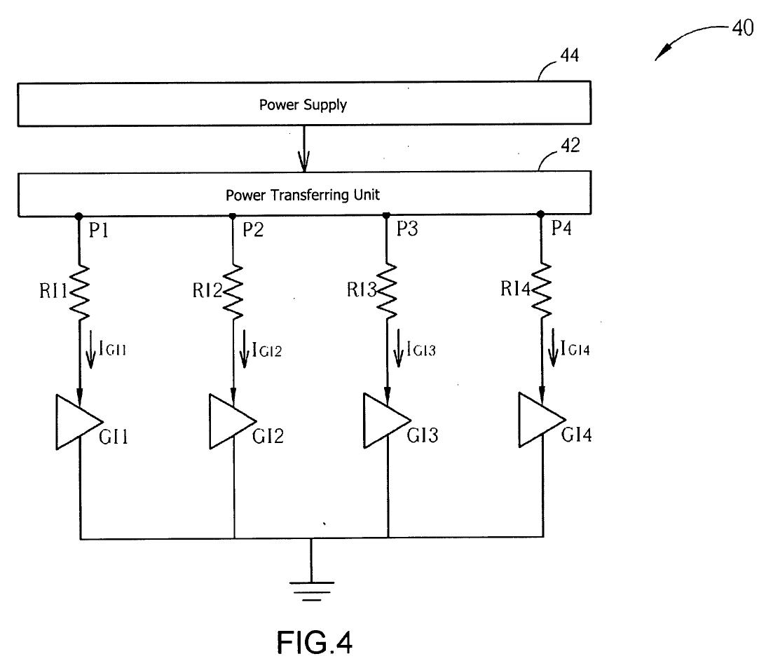

According to the IC package method 30, the die is installed on the die paddle of the lead frame. The signal terminals of the die are coupled to the fingers of the lead frame, utilizing gold wires for example. In Step 306, according to the invention, the power transferring unit is formed for transferring power. The power reception terminals of the logic units in the die are coupled to the power transferring unit. In this embodiment, each power reception terminal for receiving power that drives each logic unit is coupled to the power transferring unit, such that the supply voltage received by the logic units does not vary by impedance characteristics of interconnections between the logic units, as shown in FIG. 4. In FIG. 4, G11, G12, G13 and G14 represent logic units of a logic circuit 40, and I_{G11}, I_{G12}, I_{G13} and I_{G14} represent currents consumed by the logic units G11, G12, G13 and G14, respectively. Power reception terminals P1, P2, P3 and P4 of the logic units G11, G12, G13 and G14 are coupled to a power transferring unit 42, respectively, for receiving power from a power supply 44. As shown in FIG. 4, the logic units G11, G12, G13 and G14 are individually coupled to the power transferring unit 42. Thus, toggling of any of the logic units does not affect power received by the remaining logic units so as to avoid the IR drop issue. It should be noted that FIG. 4 is merely illustrative on principles of the IC package procedure 30, and elements including signal terminals, and the lead frame are omitted for succinctness.

In the IC package procedure 30, the die paddle may be coupled to a ground terminal, and a plurality of ground terminals of the die may be coupled to the die paddles, so as to avoid the ground voltage of the logic units from fluctuating. In addition, the power transferring unit may be realized by allocating one power finger of the fingers as the power transferring unit. The power reception terminals of the plurality of logic units are directly coupled to the power finger. Alternatively, an electrically-conducting material may be applied to form the power transferring unit by way of a bus-like structure.

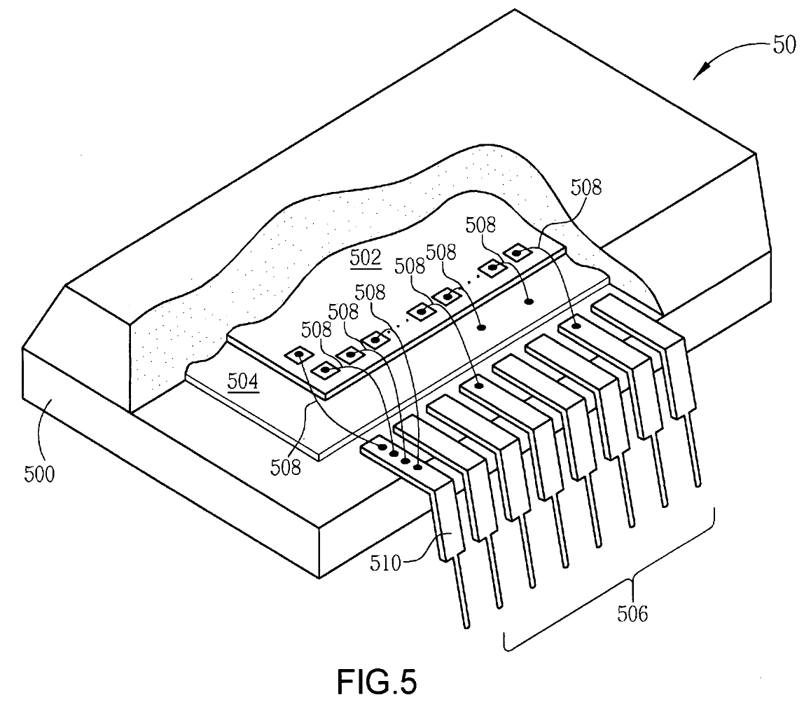

Refer to FIG. 5 showing a sectional view of an IC apparatus 50 according to one embodiment of the invention, comprising a die 502, a die paddle 504, fingers 506, gold wires 508 and a housing 500. The die 502 serving as a core unit of the IC apparatus 50 performs analog and/or digital signal processing. The die paddle 504 and the fingers 506 form a lead frame for holding the die 502 and soldering the gold wires 508, so as to conduct signals with high quality. The housing 500 fills up a cavity for protecting the IC apparatus 50, and may be made of ceramic or plastic such as epoxy molding compound (EMC). Further, in the IC apparatus 50, a power finger 510 can be applied as the power transferring unit. The power reception terminals of the logic units in the die 502 are directly coupled to the power finger 510.

Via the IC apparatus 50, the power reception terminals of the logic units are coupled to the power finger 510. Therefore, the supply voltage received by the logic units does not vary by impedance characteristics of connections between the logic units so as to decrease IR drop. In addition, the die paddle 504 is coupled to a ground terminal (not shown in FIG. 5), and a plurality of ground terminals of the die 502 are coupled to the die paddle 504, so as to avoid the ground voltage of the logic units from fluctuating. The IC apparatus 50 may by provided with another power finger at a different position for a different voltage, with appropriate insulation.

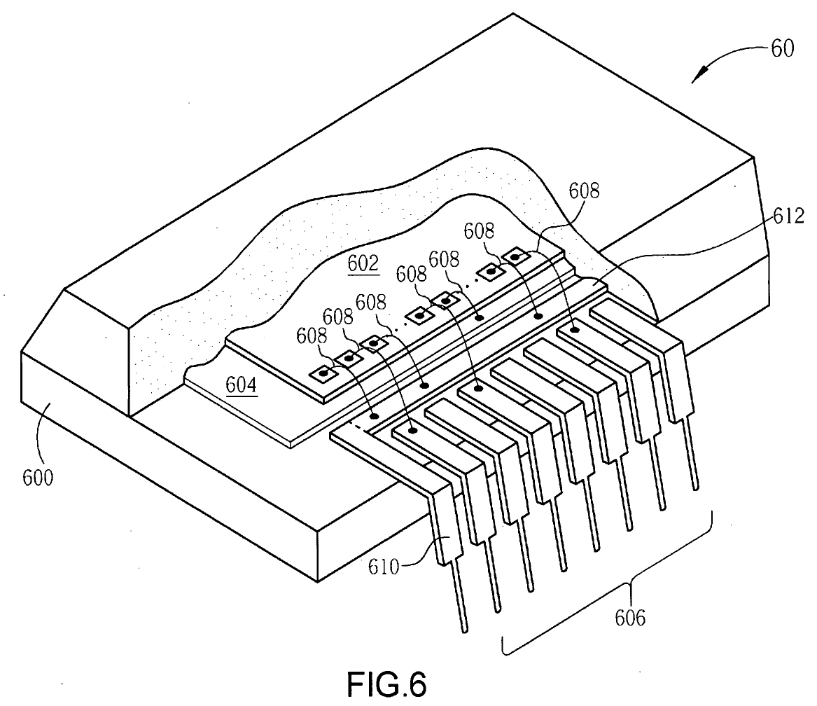

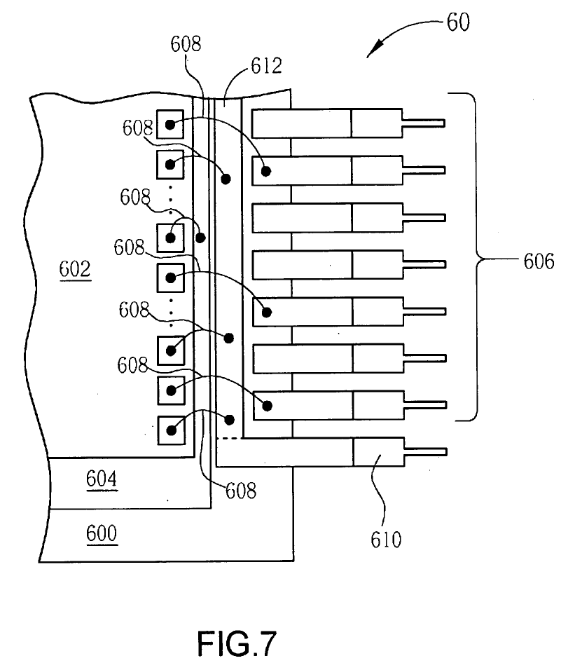

FIG. 6 shows a sectional view of an IC apparatus 60 according to one embodiment of the invention. FIG. 7 shows a top perspective view of the IC apparatus 60. The IC apparatus 60 comprises a die 602, a die paddle 604, fingers 606, gold wires 608, a housing 600 and a power transferring unit 612. In the housing 600, the power transferring unit 612 locates at an area different from that of the die paddle 604, and is extended from a power finger 610. Power reception terminals of the logic units in the die 602 are coupled to the power transferring unit 612.

Via the IC apparatus 60, the power reception terminals of the logic units are coupled to the power transferring unit 612. Therefore, the supply voltage received by the logic units is not altered by impedance caused by interconnections between the logic units so as to decrease IR drop effect. In addition, the die paddle 604 is coupled to a ground terminal (not shown in FIG. 6 and FIG. 7), and a plurality of ground terminals are coupled to the die paddle 604, so as to avoid the ground voltage of the logic units from fluctuating. The IC apparatus 60 may be provided with another power transferring unit at a different position for supplying a same or different voltage, with appropriate insulation.

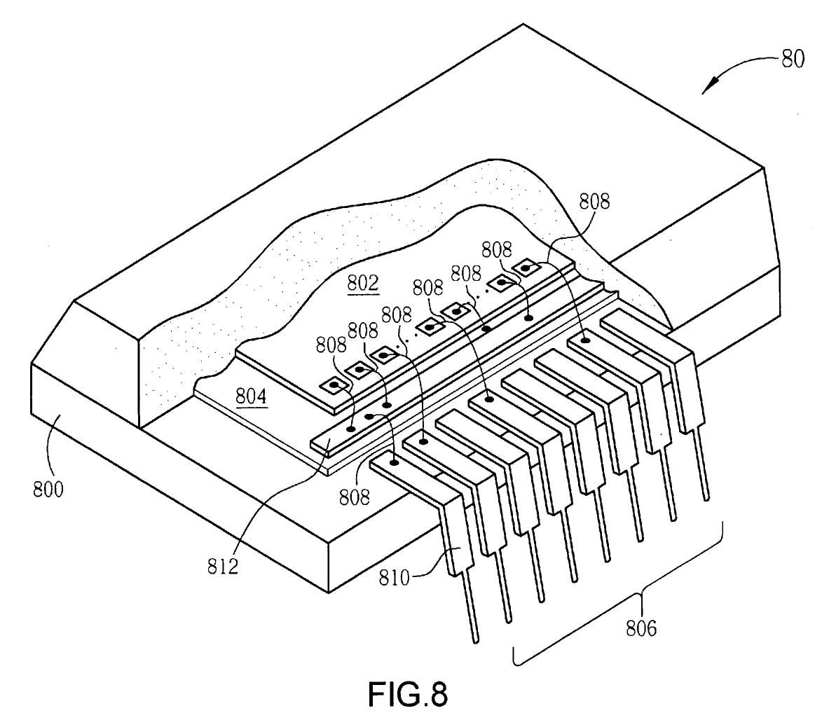

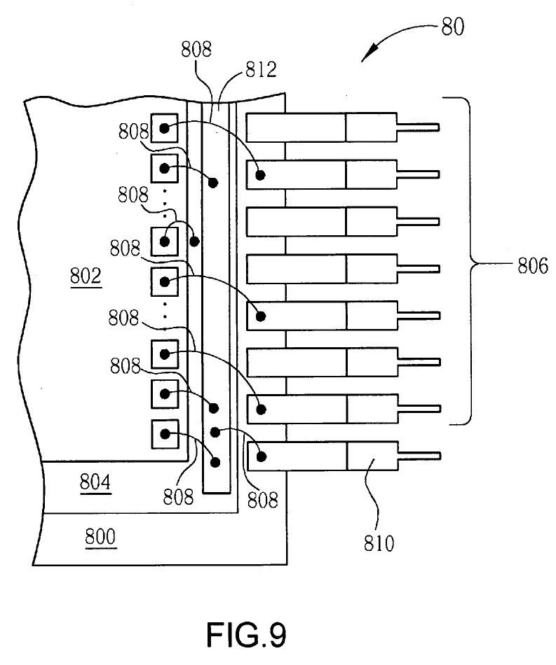

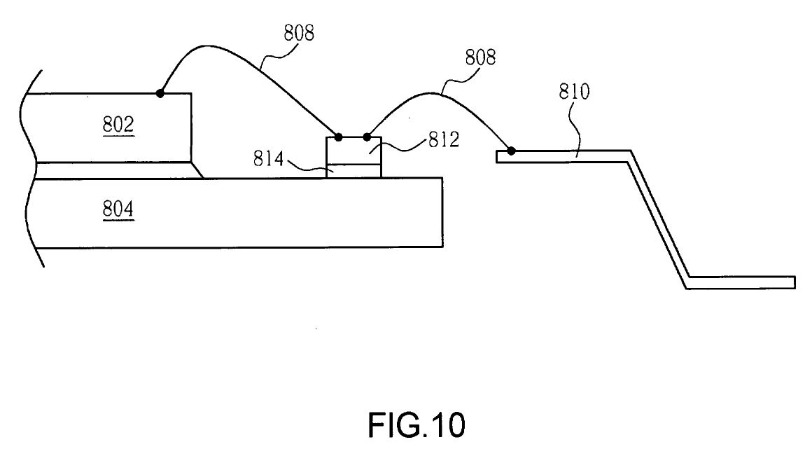

FIG. 8 shows a sectional view of an IC apparatus 80 according to one embodiment of the invention. FIG. 9 shows a top perspective view of the IC apparatus 80. FIG. 10 shows a side perspective view of the IC apparatus 80. The IC apparatus 80 comprises a die 802, a die paddle 804, fingers 806, gold wires 808, a housing 800 and a power transferring unit 812. The power transferring unit 812 is formed on top of the die paddle 804 in the housing 800. Between the power transferring unit 812 and the die paddle 804, an insulating unit 814 is preferably provided for insulating the power transferring unit 812 from the die paddle 804. The power transferring unit 812 is coupled to the power fingers 810 via the gold wires 808. Power reception terminals of logic units in the die 802 are coupled to the power transferring unit 812.

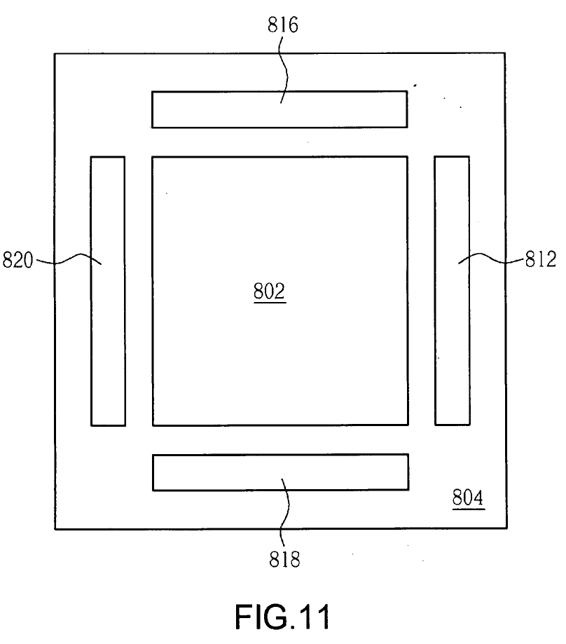

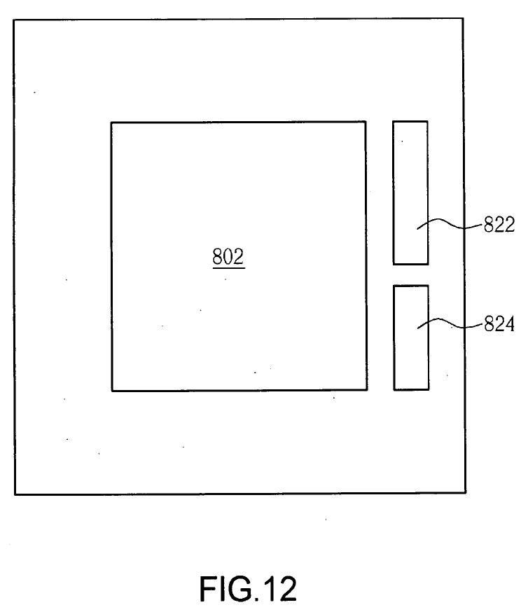

Via the IC apparatus 80, the power reception terminals of the logic units are coupled to the power transferring unit 812. Therefore, the supply voltage received by the logic units is not altered by impedance caused by interconnections between the logic units so as to decrease IR drop effect. In addition, the die paddle 804 is coupled to a ground terminal (not shown in FIGS. 8 to 10), and a plurality of ground terminals are coupled to the die paddle 804, so as to avoid the ground voltage of the logic units from fluctuating. The IC apparatus 80 may by provided with another power transferring unit at a different position to correspond to a same or different voltage, with appropriate insulation, as shown in FIG. 11 and FIG. 12. In FIG. 11, three remaining sides of the die 802 are provided with power transferring units 816, 818 and 820 corresponding to different voltages, with an insulating unit located between every two adjacent power transferring units. In FIG. 12, the power transferring unit 812 is divided into power transferring subunits 822 and 824 corresponding to different voltages adapted for multi-voltage chip operations.

In summary, according to the invention, the power reception terminals of the logic units are coupled to the power transferring unit, such that the supply voltage received by the logic units does not vary by impedance caused by interconnections between the logic units. Thus, IR drop is decreased to elevate system stability while also rendering lowered manufacturing cost.

While the invention has been described in terms of what is presently considered to be the most practical and preferred embodiments, it is to be understood that the invention needs not to be limited to the above embodiments. On the contrary, it is intended to cover various modifications and similar arrangements included within the spirit and scope of the appended claims which are to be accorded with the broadest interpretation so as to encompass all such modifications and similar structures.

What is claimed is:

1. An IC package method capable of decreasing IR drop in a chip, comprising:
forming a lead frame including a die paddle and a plurality of fingers;
installing a die on the die paddle and coupling a plurality of signal terminals of the die to the fingers;
forming a power transferring unit coupled to a power supply;
coupling power reception terminals of a plurality of logic units in the die to the power transferring unit; and
forming a housing for encapsulating the die, the lead frame, and the power transferring unit.

2. The IC package method as claimed in claim 1, wherein the die paddle is coupled to a ground terminal.

3. The IC package method as claimed in claim 2, further comprising coupling a plurality of ground terminals of the die to the die paddle.

4. The IC package method as claimed in claim 1, wherein the power transferring unit is one of the fingers.

5. The IC package method as claimed in claim 1, wherein the power transferring unit is coupled to a power supply via one of the fingers.

6. The IC package method as claimed in claim 1, wherein the power transferring unit is formed at an area off from the die paddle in the housing.

7. The IC package method as claimed in claim 1, wherein the power transferring unit is formed on top of the die paddle.

8. The IC package method as claimed in claim 1, wherein an insulating unit is provided between the power transferring unit and the die paddle.

9. The IC package method as claimed in claim 1, wherein the power transferring unit comprises a plurality of power transferring subunits, wherein each power transferring subunit corresponds to a specific voltage.

10. The IC package method as claimed in claim 9, wherein an insulating unit is provided between every two adjacent power transferring subunits of the plurality of power transferring units.

11. An IC apparatus capable of decreasing IR drop, comprising:
a lead frame, including a die paddle and a plurality of fingers;
a power transferring unit, coupled to a power supply;
a die, installed on the die paddle, the die comprising a plurality of signal terminals coupled to the fingers, and a plurality of power reception terminals coupled to the power transferring unit; and
a housing, for encapsulating the die, the lead frame, and the power transferring unit.

12. The IC apparatus as claimed in claim 11, wherein the die paddle is coupled to a ground terminal.

13. The IC apparatus as claimed in claim 12, wherein the die further comprises a plurality of ground terminals coupled to the die paddle.

14. The IC apparatus as claimed in claim 11, wherein the power transferring unit is one of the fingers.

15. The IC apparatus as claimed in claim 11, wherein the power transferring unit is coupled to the power supply via one of the fingers.

16. The IC apparatus as claimed in claim 11, wherein the power transferring unit is formed at an area off from the die paddle in the housing.

17. The IC apparatus as claimed in claim 11, wherein the power transferring unit is formed on top of the die paddle.

18. The IC apparatus as claimed in claim 17, further comprising an insulating unit provided between the power transferring unit and the die paddle.

19. The IC apparatus as claimed in claim 11, wherein the power transferring unit comprises a plurality of power transferring subunits, wherein each power transferring subunit connects to a specific voltage.

20. The IC apparatus as claimed in claim 19, further comprising a plurality of insulating units provided between adjacent power transferring subunits among the power transferring units, respectively.
